(19) United States
(12) Patent Application Publication
(10) Pub. No.: US 2008/0014720 A1
(43) Pub. Date: Jan. 17, 2008

(54) Street smart wafer breaking mechanism

(75) Inventor: John Tyler, Santa Rose, CA (US)

Correspondence Address: Tue Nguyen, 496 Olive Ave., Fremont, CA, 94539, US

(73) Assignee: Dynatex International

(21) Appl. No.: 11/724,926

(22) Filed: Mar. 15, 2007

Related U.S. Application Data
(60) Provisional application No. 60/783,158, filed on Mar. 16, 2006.

(51) Int. Cl. B26F 3/00; H01L 21/00

(52) U.S. Cl. 438/462; 225/93; 257/E21.001

(57) ABSTRACT

The present invention discloses a Street Smart breaking technique for breaking a wafer into individual dies with minimal damage to the devices on the wafer surface by applying forces only on the street areas of the wafer. The disclosed wafer breaking mechanism comprises a breaking bar creating a fulcrum against an anvil mechanism pressing only to the streets. A force is applied to the breaking bar with the scribed line acting as a stress concentrator. The applied force is increased until the wafer breaks, which it does commencing at the scribed line and propagating straight down through the wafer until the parts of the wafer on both sides of the breaker bar separate from each other.

This application claims priority from U.S. provisional patent application Ser. No. 60/783,158, filed on Mar. 16, 2006, entitled “Street Smart Wafer Breaking Mechanism” which is incorporated herein by reference.

### FIELD OF THE INVENTION

The present invention relates generally to the field of materials processing and more particularly to an apparatus and method of breaking frangible brittle semiconductor substrates into individual dies.

### BACKGROUND OF THE INVENTION

In the manufacture of microelectronic devices, such as integrated circuits, a plurality of such devices are fabricated as individual dies on a single semiconductor wafer. After the completion of the fabrication processes, the devices are tested and the dies are separated, typically by scribing and singulating into individual dies. The individual dies are then packaged, ready for board level integration.

The wafers are typically designed with horizontally and vertically extending “streets” between the dies to facilitate the separation of the individual dies. There are two conventional techniques for the separation of semiconductor wafers into individual dies after fabrication. These are: cutting and scribe and break. The cutting operation is typically a sawing process, using a rotating circular abrasive saw blade. This process is efficient for traditional silicon and III-V substrates, but not working well for new substrate materials such as sapphire due to its inherent hardness and strength. Further, sawing creates debris such as wafer particles and dust, thus requiring additional processes washing and clean up, which might damage fragile device structures. Other methods for cutting wafer into individual dies include a laser beam or a combination of laser beam and saw blade.

In the scribe and break operation, the wafer is scribed along the entire length of the street. The scribe is created either by a diamond scribe tool scratching the wafer surface, or a laser or saw cutting a shallow trench in the surface of the wafer. A wet or dry etch can also be used to create such a trench. A force is then applied to the wafer which stresses the wafer and causes it to break along the scribe lines. In this way the wafer is separated into individual die. This force may be applied via a roller, a dome press, or other pressure technique. Typical breaking mechanisms also apply force to both sides of the semiconductor wafer as part of the breaking procedure. There are many types of semiconductor wafers, some of which would be damaged if force were applied to the top surface of the wafer. To avoid contacting the top surface, vacuum suction can be applied to the backside of the wafer, but the suction is typically not strong enough to withstand the stress caused by the breaking mechanism.

### SUMMARY OF THE INVENTION

The present invention discloses a Street Smart breaking technique for breaking a wafer into individual dies with minimal damage to the devices on the wafer surface by applying forces only on the non-sensitive areas of the wafer. The disclosed wafer breaking mechanism comprises a breaker bar creating a fulcrum over which the wafer is stressed during the breaking process. On the top side of the wafers is an anvil mechanism that pushes the wafer against the breaker bar. The contact points of the breaker bar and the anvil mechanism are designed to contact only the non-sensitive areas of the wafer such as the streets and the back of the wafer. A force is applied by the anvil mechanism to the wafer with the scribe line acting as a stress concentrator. The applied force is increased until the wafer breaks, which it does commencing at the scribe line and propagating straight down through the wafer until the parts of the wafer on both sides of the breaker bar separate from each other.

In a preferred embodiment of the present invention, the wafer is a semiconductor wafer comprising a plurality of dies separated by a plurality of crossing streets, designed by semiconductor operations to facilitate the dicing of individual dies. The streets are the non-sensitive areas of the wafer, permitting top surface contact without any damage to the devices in the dies. The anvil mechanism preferably comprises two top down bars with an adjusting mechanism to adjust the distance between the two bars to ensure that the top down bars contacts are directly onto the streets of the wafer. The top down bars preferably have a sharp edge to minimize the contact area with the wafer. The breaker bar is contacting the back side of the wafer, directly under a middle street between the two streets that the top down bars are contacting. By moving the top down bars relative to the breaker bar, the wafer is stressed with the scribed line acting as a stress concentrator, and the break would commence at the scribe line and propagate down the wafer.

The present invention further provides optional improvements such as a plurality of top down bars and breaker bars, and an automation system with X-Y movement and rotation to perform the separation of all individual dies in a wafer.

### BRIEF DESCRIPTION OF THE DRAWINGS

FIG. 1 shows the design of semiconductor wafer with non-sensitive areas of streets.

FIG. 2 shows an embodiment of the present invention breaking mechanism.

FIGS. 3A and 3B show a typical operation of the present invention breaking mechanism.

FIG. 4 shows an exemplary curved linear mechanism for the support chuck.

FIGS. 5A and 5B show an exemplary piezoelectric sub-micron movement mechanism for the contact bars.

FIG. 6 shows an exemplary street breaking assembly.

FIG. 7 shows an exemplary street breaking mechanism.

### DETAILED DESCRIPTION OF THE INVENTION

Typical wafer breaking mechanisms apply force to the topside of the semiconductor wafer as part of the breaking procedure. However, many wafers would be damaged if forces were applied to the devices. The present invention discloses a damage-free wafer singulating technique by a breaking mechanism that contacts only the wafer non-sensitive surface areas. The present breaking technique can be easily incorporated and conveniently applicable in an IC manufacturing process without complicated processing steps. The disclosed breaking or cleaving mechanism can provide higher throughput, reduce damage and debris, less chipping and residual stress, and can achieve wafer space savings as compared to the space reserved for typical dicing processes. Additionally, the present techniques could also incorporate additional improvements such as adhesive tape, wet or dry etch, or laser applications.

The present invention discloses an apparatus and method for breaking or cleaving a semiconductor wafer into individual dies along a plurality of scribe lines without damaging the top surface by employing a breaking mechanism contacting the wafer top surface at only non-sensitive surface areas. Semiconductor wafers are typically crystalline with sufficient thickness and hardness, thus the wafers are likely to be broken or cleaved along the crystal orientation, and breaking or cleavage errors can be reduced to a minimum.

Generally speaking, an advantage of breaking instead of sawing or dicing is the reduction of wafer particles and dust debris which requires an additional process step of washing and clean up, which might create damage to fragile wafers, such as micro electronic mechanical systems (MEMS), or micromechanical devices. Breaking or cleaving can be achieved with essentially no chipping, hinging or side damage, and with minimum debris. The present breaking mechanism can be applied to semiconductor wafers of a wide range of materials, including silicon, gallium arsenide, sapphire, and with or without backside metallization. Further, the present breaking mechanism can be applied to delicate wafers, such as MEMS wafers.

The basic concept of the present invention is a method and apparatus for singulating semiconductor wafers without damaging the wafer devices resulting from contacting the wafer surface. One preferred embodiment of the method comprises applying the breaking mechanism to the non-sensitive surface areas of the wafer, such as the wafer streets, to avoid damaging the wafer devices, and then the breaking mechanism applying a force to break the wafer along a scribe line. Alternatively, the force on the breaking mechanism can cleave the wafer, starting from the location where the force is applied, and creating a splitting operation along the scribe line of the wafer. The cleaving operation is similar to the breaking, with the breaking done at an edge and the break is propagating through the wafer. One preferred embodiment of the apparatus comprises a breaker bar to press on a backside of a scribe line, and an anvil mechanism to press on the non-sensitive surface areas of the wafer. By pressing the breaker bar relative to the anvil mechanism, the wafer can be broken or cleaved along the scribe line. An optional base fixture holds the wafers during the breaking operation which may be purged with nitrogen.

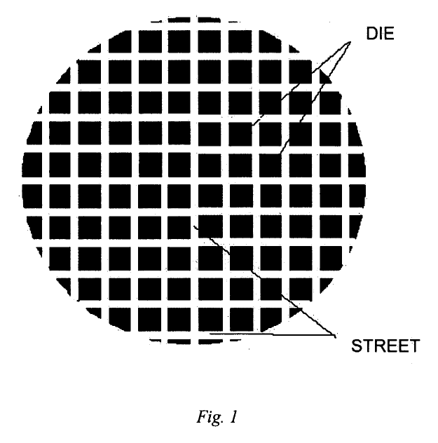

To prevent damage to the semiconductor wafer surface, the present invention breaking mechanism contacts the top surface of the semiconductor wafer only in the non-sensitive areas between the dies. Taking advantage of the design of semiconductor wafer processing where multiple dies are fabricated on the same wafer, and therefore there exists non-sensitive, non-active areas on the wafer around the individual dies to facilitate the separation of the dies. The non-sensitive areas around the dies are called streets, since it resembles a street map. FIG. 1 shows a wafer map where multiple dies are fabricated, and separated by streets. Typically, the dies are having the same area and periodically arranged on the wafer.

The die size can typically range from mm to a few cm. The streets are for separating the dies, thus are designed to occupy as little space as possible. Typically, the width of the streets are about 50 microns, though it can be wider (100 μm) or narrower. For a wafer size of 200 mm, this shows a deviation of about 1 part per 10,000. The accuracy of the streets, e.g. the positions, the direction (the straightness), or the width, are usually precisely controlled, since the device fabrication can be in the sub-micron range, thus 50 micron streets can be regarded as large in the microscopic range of device fabrication.

The die singulating process typically starts with the streets being notched or scribed as a starting point for the breaking action. The scribe process is typically accomplished by a diamond scribe, or a laser beam. Prior art breaking mechanism includes a rubber feet applied on a wide area of the scribe mark, against a breaker bar acting as a fulcrum on the backside. The rubber prevents damage to the device surface, but the force on the rubber tends to be dependent on the hardness of the substrate. Further, any contact with the active device area is generally not desirable.

The present invention discloses a three (or more) points (or lines) breaking mechanism, comprising a breaker bar position generally under the scribe mark, and two contact bars positioned generally near the scribe mark. By pressing either the breaker bar against the contact bars, or pressing the contact bars against the breaker bar, a force or a moment, can be applied to the substrate (or wafer) to break the wafer along the scribe mark.

Using the three point breaking mechanism, the substrate dependency is greatly reduced, and thus various substrates of SiC, silicon, GaAs, diamond, etc. can be singulated with consistency and repeatability.

The apparatus according to an exemplary embodiment includes a breaking mechanism for applying a force to a scribe line. The length of the applied force can varied. A force can be applied to the whole scribe line, resulting in a wafer breaking operation, a force can be applied to a segment of the scribe line, resulting in a cleavage operation propagated from where the force is applied, or any combination operation between the breaking mechanism and the cleavage mechanism. The force can be applied to the inside of the wafer, or the force can be applied over the edge of the wafer.

The breaking mechanism preferably comprises a top anvil mechanism and a breaker bar where the breaker bar has a knife-edge which applies a force to the backside of wafer at the scribe line against the anvil mechanism which presses on non-sensitive surface areas on the topside of the wafer.

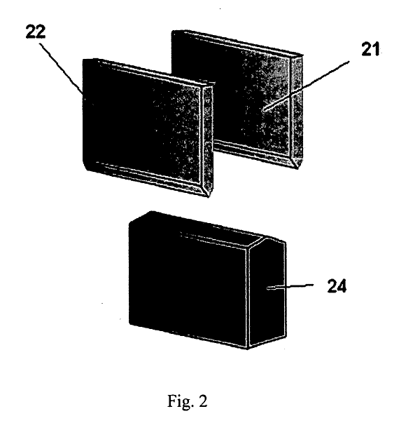

The top anvil mechanism provides the support or the downward force on the topside of the wafer. The top anvil mechanism of the present invention only applies force on the top surface of the semiconductor wafer in the non-sensitive parts of the wafer, which are the streets. In a preferred embodiment, the top anvil mechanism comprises a plurality of top down bars (or contact bars), preferably two bars, that contact the wafer's topside and an adjustment mechanism that can adjust the gap between the two adjacent bars. This allows for varying die sizes, as is common is the semiconductor manufacturing industry. FIG. 2 shows a schematic for an embodiment of the breaking mechanism, showing only two bars 21 and 22 for the top anvil. This whole top anvil mechanism can move up and down, for example, by a vertical slide assembly that is a part of a machine employing the present invention street smart breaking mechanism.

The top down bars are designed to press only the non-sensitive surface areas, preferably on the adjacent scribe lines on opposite sides of the street to be broken. The top down bars are preferably having a minimum surface contact with the wafer, such as a taper edge at the contact end. In one embodiment, the top down bars have a dull knife edge such as a taper round edge to provide a minimum contact surface while not damaging the wafer. To improve alignment, the taper edge is preferably positioned toward the outer side of the top down bar, leaving the dies to be broken or cleaved clear from obstruction. The top down bar is preferably a bar, but can be a pointed cylinder to press on the wafer at a point, or a cross shape surface to press on the wafer at the intersection of the streets.

On a full wafer, the streets are intact, and the top down bars can be pressing anywhere within the streets, such as in the middle of the streets. However, the contact bars are preferably pressing between the scribe mark and the other end of the streets. On a partial wafer where the streets have been broken, the top down bars can press on the inside half of the streets to form the anvil mechanism for the breaker bar.

The breaker bar 24 is preferably a static bar that provides the fulcrum over which the wafer is stressed during the breaking process as shown in FIG. 2. A plurality of breaker bars can be used for simultaneously multiple breaking operations. The breaking operation resulted from the applied force resulting from the relative movement of the top anvil mechanism and the breaker bar. The applied force can be an impulse which imparts a shock to the wafer to produce a fracture. The force can be a gradual force which provides a gradually increased stress or strain to the wafer to produce a fracture. The force can be applied to the whole length of the wafer or the wafer segment, resulting in a breaking operation. The force can be applied to an inside portion of the wafer or the wafer segment, resulting in a breaking operation. The force can be applied to an edge portion of the wafer, resulting in a cleavage operation that propagates throughout the length of the scribe line.

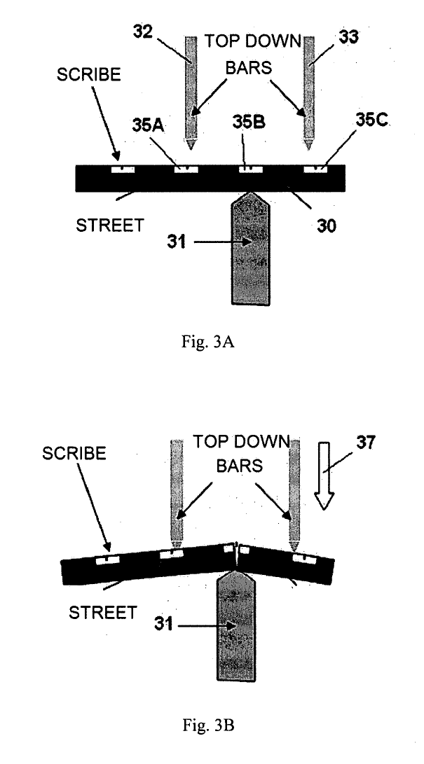

FIGS. 3A and 3B show a preferred embodiment of the sequence of operation. FIG. 3A shows the wafer 30 to be broken and the street smart mechanism (comprising the breaker bar 31, and the top down bars 32 and 33 of the top anvil mechanism) are aligned such that the breaker bar 31 is directly below and parallel to the street 35B to be broken and the top down bars 32 and 33 in the top anvil mechanism are directly above, parallel to but not in contact with the two streets 35A and 35C immediately adjacent to the street 35B to be broken. FIG. 3B shows the top down bars 32 and 33 in the top anvil mechanism are driven down to the wafer 30 surface and a controlled force 37 is applied. As a result of the downward force, the wafer is bent over the breaker bar 31 such that the top surface of the wafer 30 is in tension while the bottom surface is in compression. The scribe line acts as a stress concentrator. The force is increased until the wafer breaks, which it does commencing at the scribe line and propagating vertically down through the wafer until the parts of the wafer either side of the breaker bar separate from each other. Then the wafer is indexed to the next street and the process is repeated. After the first pass, the wafer is broken into individual strips.

The wafer is then rotated 90 degrees, and the strips are then broken into individual dies. The wafer is typically placed on an adhesive flexible membrane or wafer stretch tape to secure the wafer to the tape. This adhesive tape can hold the individual strips and dies in place during the breaking process.

The wafer is typically scribed to ensure a clean break. The scribe can be performed with a diamond scriber or a laser beam scribe. A wet chemical etch or a dry etch process can also be applied to anisotropically etch the semiconductor wafer into a V-shaped groove in the scribe lines before the mechanical force is applied. Further, an optional vacuum chuck positioned beneath the wafer surface can be used, to supplement the top surface force from the anvil mechanism above the wafer surface, permits a reduction in the top surface force.

The disclosed Street Smart breaking mechanism can be used as a subassembly in a computer controlled wafer-breaking system. The main system would comprise an optional drive mechanism for X, Y, and Theta wafer positioning, computer electronics and motion control system and machine vision system. The optional drive mechanism can move the breaking mechanism to the next scribe line. The drive mechanism preferably automatically steps the position of the wafer relative to the breaking mechanism and further actuates the breaking mechanism to break the wafer at the next scribe line. The drive mechanism can preferably comprise a rotation operation to allow the breaking at crossed scribe lines.

The optional drive mechanism of the present invention can comprise an X-table, mounted on a base unit, movable back and forth in the X-direction under computerized control of an X-direction motor. A Y-table is mounted atop the X-table, and is movable back and forth, relative to the X-table, in the Y-direction under computerized control of a Y-direction motor. A wafer-holding chuck is mounted on the Y-table for rotational movement about an axis perpendicular to the surfaces of the X and Y tables, under computerized control of a theta-direction motor. The wafer-holding chuck is essentially an annular ring mounted above a chamber cavity formed in the X and Y-tables.

One of the difficulties with implementing the present invention of contacting the non-sensitive areas of the wafer is the consistent accuracy in a repeatable procedure. A typical street is about 50 μm wide with a scribe mark in the middle. A diamond scribe mark is a few microns wide, but a laser scribe mark could be tens of microns wide, leaving about 20 μm width for the contact bar to press on. Thus one of the first precision requirements is the accuracy of the scribe mark, preferably repeatably in the center of the streets with minimum deviation. This requirement leads to an embodiment of the present invention, an integrated scribe module with a breaker module, thus the accuracy of the scribe module is assured when performing a breaking operation in the breaker module.

The contact bar is preferably contacting the middle of the 20 μm width, within a width of 10 μm or so, thus leaving about 5 μm at the edge of the device area. This will allow some curvature of the tip of the contact bars. The street can be recessed, thus the tip of the contact bar can be sharp at one edge (the edge facing the device) to clear the recess, and less sharp at the other edge (the edge facing the scribe mark).

The breaker bar will need to be position parallel to a motion of the assembly, for example, along the X-direction. The straightness, the flatness and the direction of the breaker bar is a requirement for achieving the accuracy of the present invention. The breaker bar has a tip to press on the backside of the scribe mark. In general, the precision of the breaker bar is not as critical as the other components, since the breaker bar is typically pressed against the non-sensitive backside of the wafer.

The contact bars can require higher precision than the breaker bar. Basically, the contact bars need also to be straight, flat, parallel to each other and to the breaker bar, and located precisely over the street area. For straightness, hard materials such as stainless steel can provide some advantages of easily machining and maintained. The deviation of the straightness is critical, since the combined variation is about 5 μm for a length of the diameter of the wafer (typically 150, 200 mm, and can be 300 mm or higher).

For flatness, softer materials such as hard plastic of Delrin (and others) can provide better conformality for flatness compensation. One purpose of the flatness requirements is to ensure even pressure on the wafer. The wafers might not be perfectly flat, and the flatness might vary from one wafer to the next. Also there might be some bumps or valleys within the wafer. Thus a softer materials can deform somewhat to provide an even pressure against the wafer for even breaking. For the first pass of breaking wafer into strips, the flatness can be not as critical as in the second pass of breaking the strips into individual dies. Since the strips are separated, non-even pressure can leave certain strips not broken.

The soft material can also help in prevent damage to the active devices in the sensitive area. The contact bars are preferably contact only the non-sensitive area, but due to tolerance variation, occasionally, a contact bar can contact the vicinity of the interface between the sensitive and non-sensitive area. The soft material of the contact bar tip would prevent severe damage in this case.

In an exemplary embodiment, the present invention discloses that the flatness compensation can be more critical than the straightness requirement, thus the contact bars are made of softer material for allowing the flatness flexibility. The material of the contact bar also should be hard enough to be within the ball park of the straightness requirement. The extra straightness requirement, if needed, can be met by compensating with other components.

In an exemplary embodiment, the present invention employs a composite material for the contact bars. The composite contact bar comprises a soft material (e.g. hard plastic) for the contact tip and a hard material (e.g. steel, stainless steel) for the bar spine. The soft tip can provide the flatness compensation, and the hard spine can provide the straightness requirement. The composite contact bar can be a soft material with a hard spine insert, a hard material with a soft tip insert, or a hard material section with a soft material section bonded together. The composite contact bar can be a hard bar with soft coating (such as Teflon coating), or aluminum/anodized aluminum composite.

The contact bars are set up to be parallel to each other and to the breaker bar. Together with the straightness requirement, the parallel requirement serves to ensure that the deviation of the contact bars is within the street area (e.g. 5 μm from the center point of contact) for the length of the wafer (typically 200 mm wafer).

After the setup of the breaker bar and the contact bars, the scribed wafer is disposed on a support chuck, which then positions itself between the breaker bar and the contact bars. In this disclosure, the breaker is depicted as in the bottom position, under the wafer, with the contact bars in the top position on the wafer. However, the breaker bar and the contact bars can be at the top or the bottom positions, as long as they are in the opposite side of the wafer.

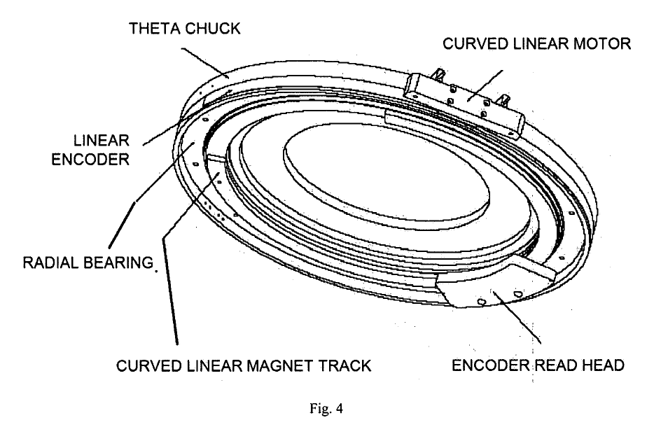

The support chuck is then rotated to align the direction of the streets with the direction of the bars. This is also part of the critical tolerance requirement where roughly 5 μm variation is needed for the length of the wafer. In an embodiment, the present invention employs a direct position reading using a curve linear encoder read head. As shown in FIG. 4, the encoder is located in the outer peripheral of the support chuck, thus allowing the direct reading of the position of the chuck. This direct reading potentially improves the accuracy of the alignment process since it eliminates indirect position reading (such as motor encoder where the position of the motor is read, and then translated using the actual gear set for the chuck). The linear encoder also potentially provides more space for the encoder head, thus can produce better accuracy.

In an embodiment, the support chuck is rotated using a curved linear motor mechanism. The curved linear mechanism provides high power and high accuracy over that of a rotation motor. The incorporation of the curved linear motor by the present invention is estimated to provide 100-1000× better in accuracy with the same space requirements. The curved linear mechanism shown in FIG. 4 comprises a curved linear magnet track, powered by a curved linear motor, and moving the theta chuck along a set of radial bearing.

After the direction alignment, the chuck is positioned so that the breaker bar is directly aligned with a scribe line. The selection of the first breaking scribe line is generally performed with the aid of a vision recognition system to identify the location marked at the first scribe line to be broken. Generally, the first scribe line is the first scribe line at one end of the wafer. In the event of failure, e.g. due to unreadable signal, a second scribe line can then be chosen.

Then the contact bars are moving to position themselves in the non-sensitive area of the streets. The combine accuracy of this movement is within the e.g. 6 μm tolerance allowed for a street wide of 50 μm. Thus the contact bar movement mechanism is preferably sub-micron accuracy. Further, the die size can vary greatly, thus the maximum travel distance of the contact bars could be a few inches. Also the force and space requirements for the contact bars are demanding, needing high force to break the wafer, and requiring small space for accommodating the whole assembly. The contact bars are preferably centered on the breaker bar to provide balance. But at the wafer edge, or in special circumstance, non-centered mode can be used.

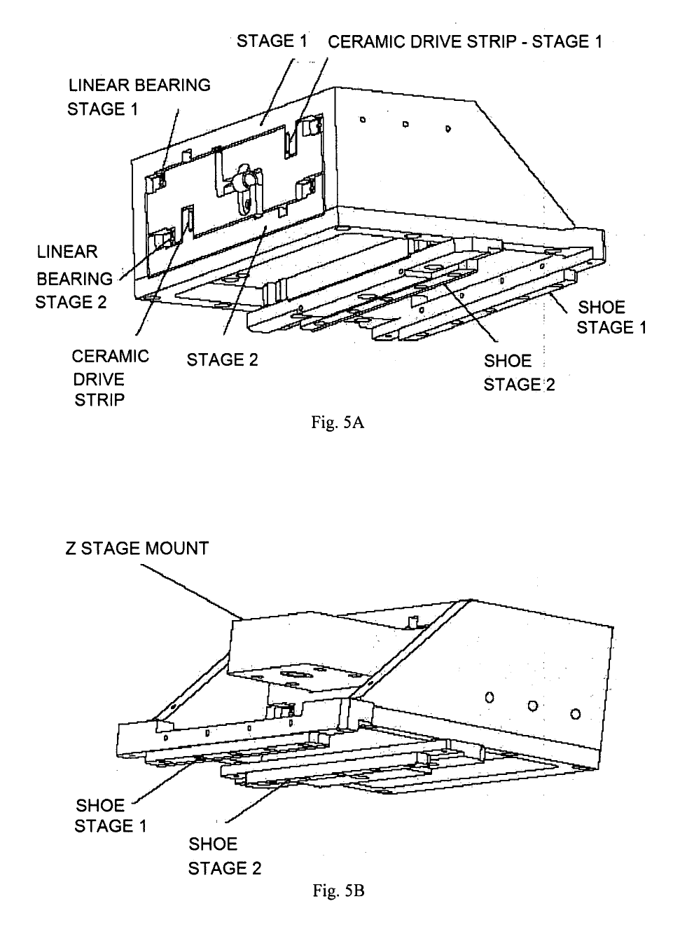

FIGS. 5A and 5B show two different views of the contact bar movement mechanism, using an ultrasonic motor. The motor employs piezoelectric effect in piezoceramics converts electrical field to mechanical strain. Under the electrical excitation and the ceramic of the motor, longitudinal extension and transverse bending oscillation modes creates a small elliptical trajectory of the ceramic edge. The ceramic edge is then coupled to a precision stage, causing stage movement. The motor is preferably operated at ultrasonic frequency, and is capable of nanometer step accuracy.

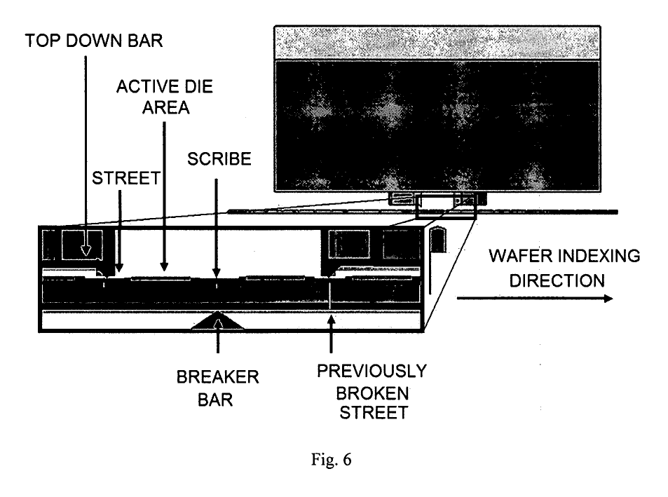

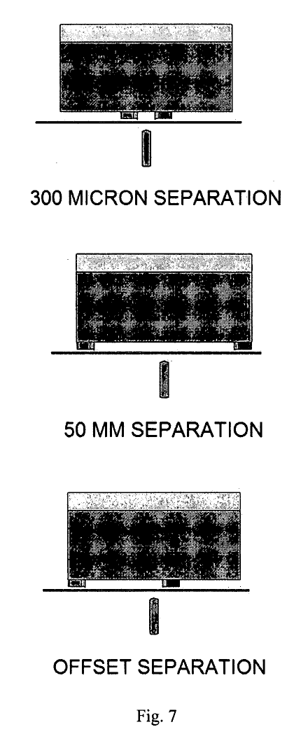

The contact bar movement is mounted on a z-stage mount, thus moving along with the up/down motion. The contact bars comprise shoes for two stages, which are driven by the moving mechanism. FIG. 5A also shows the linear bearing and the ceramic drive strip of the motor. The motors of sub-micron accuracy is needed to achieve the needed accuracy, thus the piezoelectric motor is an exemplary motor. FIG. 6 and FIG. 7 show an exemplary street breaking assembly and a street breaking mechanism.

For operation requiring scribe marks, the present invention further provides an optional scribe station, which could be integrated with the breaking station, or could be a separate station.

For separate scribing and breaking stations, the drive mechanism can provide the movement between these two separate stations. At the scribing station, a scribe module is mounted above the wafer-holding chuck. At the breaking station, an anvil is located above the wafer-holding chuck. An impulse bar with a straight sharp upper edge mounted beneath the wafer-holding chuck is carried by the X-table along with the wafer chuck, to both scribe and break stations.

During scribing, the wafer-holding chuck carries a wafer to the scribing station at which time the upper sharp edge of the impulse bar rises against the bottom surface of the wafer along a line in the X-direction. The wafer is moved relative to the diamond scribe in the X-direction to scribe the wafer in a line directly above the elongated sharp edge of the impulse bar. At the completion of a single scribing step, as described, the impulse bar remains in position, scribe the tool retracts from the wafer surface, the wafer is stepped a predetermined distance in the Y-direction, and the foregoing operation is repeated to draw a second scribe line in the X-direction separated from the first scribe line by a programmed Y-distance. This process is then repeated until all desired scribing has been completed in a first direction.

The annular wafer chuck is then rotated 90 degrees and the process repeated to scribe the wafer along lines perpendicular to the first set of scribes.

Once scribing has been completed, the X-table moves the impulse bar and wafer chuck along the X-axis to the breaking station beneath the anvil. In this position the anvil is moved to a predetermined distance above the wafer, and the Y-table moves the wafer in the Y-direction to position its first scribe line above the sharp edge of the impulse bar and beneath the anvil. Once so positioned, the impulse bar is forced upwardly to pinch the wafer scribe line between the anvil and the sharp edge of the impulse bar, thereby breaking the wafer along that scribe line. Once the break has been completed, the impulse bar is retracted and the wafer chuck moved a programmed Y-distance to bring the next adjacent scribe line into alignment with the sharp edge of the impulse bar. Once aligned, the impulse bar is again driven upwardly against the bottom of the wafer to break the wafer along said second scribe line. This process is repeated until all second direction scribe lines have been broken. The theta table then rotates the chuck 90 degrees and the same process is repeated to break all scribe lines perpendicular to the scribe lines first broken.

All of the foregoing movements are driven by individual motors under control of a computer system whereby the foregoing operations can be carried out with great precision and without operator intervention. For example, the scribe module includes an electric motor consisting of a linear voice coil actuator and position sensor which moves the diamond-tipped scribing tool of the module in a linear direction under motor control toward and away from the wafer surface.

Alignments of the wafer position for the scribing and breaking stations are carried out by means of a computer system which includes a color video camera, video image control circuitry, and a video monitor. All misalignments visually detected on the monitor can be manually corrected by the operator or automatically corrected by the computer using pattern recognition software techniques.

In an alternate preferred embodiment, the scribe station and the breaking station can be integrated. The anvil mechanism above the wafer according to the present invention can be designed to avoid interference with the diamond scribe movement. For example, the anvil mechanism can comprise two top down bars contacting two nearby scribe lines, leaving the center scribe line clear for the diamond scribe movement. An optional vacuum chuck can also used with vacuum applied to the wafer in the region surrounding the scribing line to be broken, i.e., in the region surrounding the point of impact of the impulse bar against the lower surface of the wafer. This additional vacuum chuck design restrains upward movement of the wafer during the breaking operation, without contacting the upper surface of the wafer.

The incorporation of the scribing station and the breaking station allows the system to know the accuracy of the scribing operation, thus can effectively design and use the breaking mechanism with the contact bars contacting only the streets.

What is claimed is:

1. A method for singulating a substrate, the substrate comprising a first surface and an opposite second surface, the first surface comprising sensitive areas and non-sensitive areas, the method comprising
aligning the non-sensitive areas of the first surface with a plurality of contact bars;
approaching the second surface with a breaker bar;
relatively pressing the contact bars with respect to the breaker bar to break the substrate along the breaker bar, the contact bars contacting the non-sensitive area of the first surface,
wherein the breaking action provides minimum damage to the sensitive area of the substrate.

2. A method as in claim 1 wherein the non-sensitive area comprises a street map.

3. A method as in claim 1 wherein the non-sensitive area is less than 100 micron wide.

4. A method as in claim 1 wherein relatively pressing the contact bars with respect to the breaker bar to break the substrate comprises applying a uniform pressure along the substrate.

5. A method as in claim 1 wherein applying uniform pressure comprises using a soft material at the tip of the contact bars for material yielding to allow for variations in substrate surface.

6. A method as in claim 1 wherein the contact bars comprise hard material spine for providing a straight line with minimum variation.

7. A method as in claim 1 wherein the contact bars comprise a hard material spine and a soft material tip.

8. A method for singulating a substrate, the substrate comprising a first surface and an opposite second surface, the first surface comprising sensitive areas and non-sensitive areas, the method comprising
providing a plurality of contact bars in the vicinity of the first surface;
providing a breaker bar in the vicinity of the second surface;
rotating the substrate to align the direction of the non-sensitive area with the contact bars;
moving the contact bars to align the non-sensitive area with the contact bars;
relatively pressing the contact bars with respect to the breaker bar to break the substrate along the breaker bar,
wherein the breaking action provides minimum damage to the sensitive area of the substrate.

9. A method as in claim 8 wherein rotating the substrate comprises a curved linear mechanism using direct position feedback for accuracy improvement.

10. A method as in claim 8 wherein moving the contact bars comprises a sub-micron piezoelectric moving mechanism for accuracy improvement.

11. A method as in claim 8 wherein aligning the contact bars within the non-sensitive area comprises contacting the contact bars in the non-sensitive area in one side of the scribe mark.

12. A method as in claim 8 wherein relatively pressing the contact bars with respect to the breaker bar to break the substrate comprises applying a uniform pressure along the substrate.

13. A method as in claim 8 wherein applying uniform pressure comprises using a soft material at the tip of the contact bars to allow for variations in substrate surface.

14. A method as in claim 8 wherein the contact bars comprise hard material spine for providing a straight line with minimum variation.

15. A method as in claim 8 wherein the contact bars comprise a hard material spine and a soft material tip.

16. A method for singulating a substrate, the substrate comprising a first surface and an opposite second surface, the first surface comprising sensitive areas and non-sensitive areas, the method comprising
scribing the substrate within the non-sensitive area;
transferring the substrate along a guideline to a breaker station, wherein the breaker station providing a plurality of contact bars in the vicinity of the first surface and a breaker bar in the vicinity of the second surface;
rotating the substrate to align the direction of the non-sensitive area with the contact bars;
moving the contact bars to align the non-sensitive area with the contact bars;
relatively moving the contact bars with respect to the breaker bar to break the substrate along the breaker bar,
wherein the breaking action provides minimum damage to the sensitive area of the substrate.

17. A method as in claim 16 wherein rotating the substrate comprises a curve linear mechanism using direct position feedback for accuracy improvement.

18. A method as in claim 16 wherein moving the contact bars comprises a sub-micron piezoelectric moving mechanism for accuracy improvement.

19. A method as in claim 16 wherein aligning the contact bars within the non-sensitive area comprises contacting the contact bars in the non-sensitive area in one side of the scribe mark.

20. A method as in claim 16 wherein relatively pressing the contact bars with respect to the breaker bar to break the substrate comprises applying a uniform pressure along the substrate.

21. A method as in claim 16 wherein applying uniform pressure comprises using a soft material at the tip of the contact bars to allow for variations in substrate surface.

22. A method as in claim 16 wherein the contact bars comprise hard material spine for providing a straight line with minimum variation.

23. A method as in claim 16 wherein the contact bars comprise a hard material spine and a soft material tip.

24. A method as in claim 16 wherein the contact bars contact the edge of the non-sensitive area.

25. A system for singulating a substrate, the system comprising
a substrate holder for supporting the substrate, the substrate comprising a first surface and an opposite second surface, the first surface comprising sensitive areas and non-sensitive areas;
a curve linear mechanism to rotate the substrate holder with direct position feedback;
a plurality of contact bars positioned near the first surface for contacting the non-sensitive area;
a feet motor to move the plurality of contact bars for micron accuracy;
a breaker bar positioned near the second surface to provide a fulcrum for the contact bars;
a breaking mechanism to move the breaker bar relative to the contact bars to break the substrate.

26. A system as in claim 25 wherein the contact bars comprise a soft material at the tip to allow for variations in substrate surface.

27. A system as in claim 25 wherein the contact bars comprise hard material spine for providing a straight line with minimum variation.

28. A system as in claim 25 wherein the contact bars comprise a hard material spine and a soft material tip.
